(19) United States
(12) Patent Application Publication
(10) Pub. No.: US 2020/0373367 A1
(43) Pub. Date: Nov. 26, 2020

(54) DISPLAY DEVICE

(71) Applicant: SHARP KABUSHIKI KAISHA, Sakai City, Osaka (JP)

(72) Inventors: TOHRU OKABE, Sakai City, Osaka (JP); RYOSUKE GUNJI, Sakai City, Osaka (JP); HIROKI TANIYAMA, Sakai City, Osaka (JP); SHINSUKE SAIDA, Sakai City, Osaka (JP); SHINJI ICHIKAWA, Sakai City, Osaka (JP); YOSHIHIRO NAKADA, Yonago-shi, Tottori (JP); HIROHARU JINMURA, Yonago-shi, Tottori (JP); AKIRA INOUE, Yonago-shi, Tottori (JP)

(21) Appl. No.: 16/961,215

(22) PCT Filed: Jan. 11, 2018
(86) PCT No.: PCT/JP2018/000469

§ 371 Date: Jul. 9, 2020

(51) Int. Cl. H01L 27/32

(52) U.S. Cl. CPC H01L 27/3248; H01L 27/3258; H01L 51/0097; H01L 27/3276; H01L 2227/323; H01L 27/3265

(57) ABSTRACT

A display device includes: a semiconductor film; an inorganic insulating film overlying the semiconductor film; and light-emitting elements overlying the inorganic insulating film, each of the light-emitting elements including a first electrode and a second electrode, wherein the inorganic insulating film has a contact hole there through, and a portion of the first electrode overlaps the contact hole so that the portion of the first electrode is in contact with the semiconductor film in the contact hole.

### TECHNICAL FIELD

The present invention relates to display devices.

### BACKGROUND ART

Patent Literature 1 discloses a structure including a planarization film below the anode (pixel electrode) of an OLED (organic light-emitting diode), the planarization film having a contact hole through which the anode is connected to the drain electrode of a TFT.

### CITATION LIST

### Patent Literature

Patent Literature 1: Japanese Unexamined Patent Application Publication, Tokukai, No. 2010-161058 (Publication Date: Jul. 22, 2010)

### SUMMARY OF INVENTION

### Technical Problem

In the structure of Patent Literature 1, the planarization film may fall short of planarizing the lumps formed by drain electrodes, which possibly adversely affects the display. There is also a problem that the formation of the planarization film is costly.

### Solution to Problem

The present invention, in an aspect thereof, is directed to a display device including: a semiconductor film; an inorganic insulating film overlying the semiconductor film; and light-emitting elements overlying the inorganic insulating film, each of the light-emitting elements including a first electrode and a second electrode, wherein the inorganic insulating film has a contact hole therethrough, and a portion of the first electrode overlaps the contact hole so that the portion of the first electrode is in contact with the semiconductor film in the contact hole.

### Advantageous Effects of Invention

A portion of a first electrode is in contact with a semiconductor film in an aspect of the present invention. The present invention, in the aspect, obviates the need for a drain electrode, thereby eliminating the possibility of a drain electrode forming a lump adversely affecting a display, and also obviates the need for a planarization film, thereby reducing costs.

### BRIEF DESCRIPTION OF DRAWINGS

FIG. 1 is a flow chart representing an exemplary method of manufacturing a display device.

FIG. 2 is a set of cross-sectional views of an exemplary structure of a display device in accordance with Embodiment 1.

FIG. 3 is an enlarged cross-sectional view of a part of FIG. 2.

FIG. 4 is a flow chart representing a method of forming a TFT layer and a light-emitting element layer in accordance with Embodiment 1.

FIG. 5 is a cross-sectional view of an exemplary display device.

FIG. 6 is a plan view of an exemplary structure of a display device.

FIG. 7 is a set of cross-sectional views of parts of FIG. 6.

FIG. 8 is a set of cross-sectional views illustrating steps of forming terminal lines in a bendable portion.

FIG. 9 is a set of cross-sectional views of an exemplary structure of a display device in accordance with Embodiment 2.

FIG. 10 is a flow chart representing a method of forming a TFT layer and a light-emitting element layer in accordance with Embodiment 2.

FIG. 11 is a set of cross-sectional views of an exemplary structure of a display device in accordance with Embodiment 3.

FIG. 12 is a flow chart representing a method of forming a TFT layer and a light-emitting element layer in accordance with Embodiment 3.

### DESCRIPTION OF EMBODIMENTS

Throughout the following description, the expression, “component A is in the same layer as component B,” indicates that components A and B are formed in the same process or step, the expressions, “component A underlies/is below component B,” indicate that component A is formed in an earlier process or step than component B, and the expressions, “component A overlies/is above component B,” indicate that component A is formed in a later process or step than component B.

### Embodiment 1

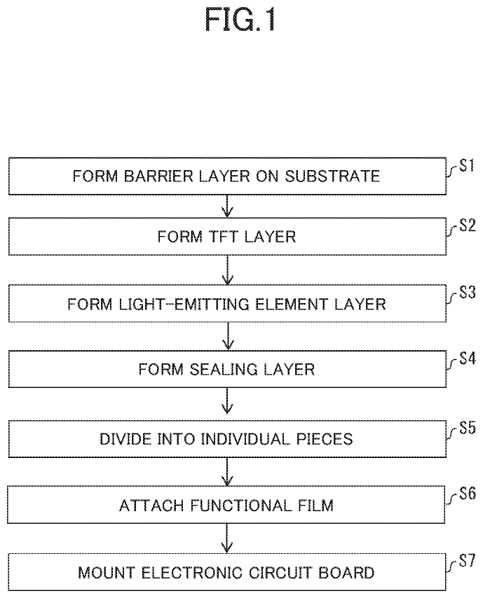

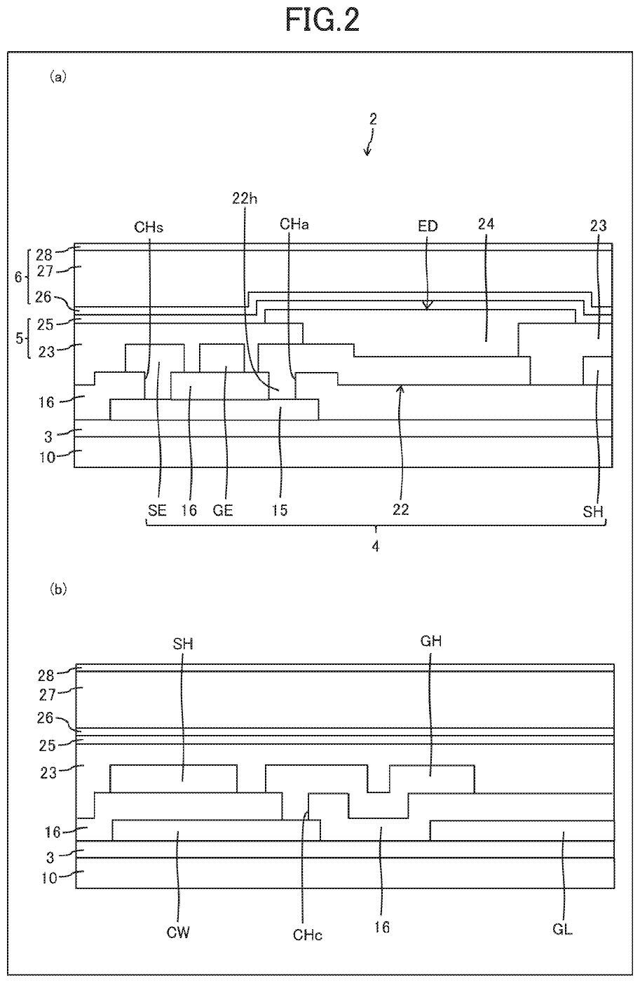

FIG. 1 is a flow chart representing a method of manufacturing a display device. FIG. 2 is a set of cross-sectional views of a display section of a display device in accordance with Embodiment 1.

To manufacture a display device, a barrier layer 3 is first formed on a substrate 10 as shown in FIGS. 1 and 2 (step S1). Next, a TFT layer 4 is formed (step S2). A light-emitting element layer 5 of a top emission type (e.g., an OLED layer) is then formed (step S3). Next, a sealing layer 6 is formed (step S4). Next, the stack of the substrate 10, the barrier layer 3, the TFT layer 4, the light-emitting element layer 5, and the sealing layer 6 is divided to obtain a plurality of display devices 2 (step S5). A functional film (not shown) having, among others, an optical compensation function, a touch sensor function, and a protection function is then attached to the display device 2 (step S6). Next, an electronic circuit board such as an IC chip (not shown) is mounted to external-connection terminals of the display device 2 (step S7). These steps are carried out by a display device manufacturing machine which will be described later.

The substrate 10 may be, for example, a glass substrate. The barrier layer (barrier film) 3 prevents foreign objects such as water and oxygen from reaching the TFT layer 4 and the light-emitting element layer 5 and includes, for example, a silicon oxide film, a silicon nitride film, a silicon oxynitride film, or a stack of these films. These films can be formed by CVD.

The TFT layer 4 includes: a semiconductor film 15; an inorganic insulating film 16 (gate insulating film) overlying the semiconductor film 15; and a gate electrode GE, a gate line GH (wiring in the same layer as the gate electrode), an anode 22, a source electrode SE, and a source line SH (wiring in the same layer as the source electrode) all overlying the inorganic insulating film 16. A thin film transistor (TFT) is structured to include the semiconductor film 15, the inorganic insulating film 16, and the gate electrode GE.

The semiconductor film 15 contains an oxide semiconductor such as an In—Ga—Zn—O-based semiconductor. An In—Ga—Zn—O-based semiconductor is a ternary oxide of In (indium), Ga (gallium), and Zn (zinc). The proportions (composition ratio) of In, Ga, and Zn are not particularly limited and may be, for example, In:Ga:Zn=2:2:1, 1:1:1, or 1:1:2. The In—Ga—Zn—O-based semiconductor may be either amorphous or crystalline.

The inorganic insulating film 16 is a silicon oxide (SiOx) film or a silicon nitride (SiNx) film, formed by, for example, CVD, or a stack of these films.

The light-emitting element layer 5 includes: an electrode cover film (bank) 23 covering an edge of the anode 22; an EL (electroluminescence) layer 24 overlying the electrode cover film 23; and a cathode 25 overlying the EL layer 24. Each subpixel includes: a light-emitting element ED including the insular anode 22 (first electrode), the EL layer 24, and the cathode 25 (second electrode); and a subpixel circuit for driving the light-emitting element ED. The electrode cover film 23 may be made of, for example, an organic material, such as polyimide or acrylic, that can be applied by coating.

The EL layer 24 includes a stack of, for example, a hole injection layer, a hole transport layer, a light-emitting layer, an electron transport layer, and an electron injection layer that are arranged in this order when viewed from the underlying side. An insular light-emitting layer is formed for each subpixel by vapor deposition or inkjet technology. In contrast, at least one of the hole injection layer, the hole transport layer, the electron transport layer, and the electron injection layer may be provided as a common layer for all the subpixels and may alternatively not be provided at all.

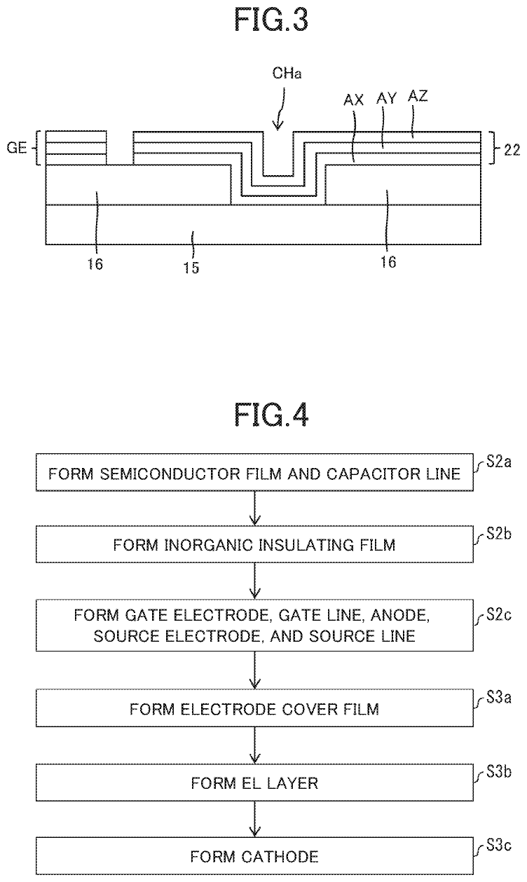

FIG. 3 is an enlarged cross-sectional view of a part of FIG. 2. Referring to FIGS. 2 and 3, the anode 22 includes a stack of an ITO (indium tin oxide) film AX (lower ITO film), a Ag-containing alloy film AY, and an ITO film AZ (upper ITO film) that are arranged in this order when viewed from the substrate 10. The anode 22 is light-reflective. The alloy film AY is sandwiched by the two ITO films AX and AZ.

The gate electrode GE, the gate line GH, the anode 22, the source electrode SE, and the source line SH are all formed in the same process (i.e., formed of the same material in the same layer). The cathode 25 may be formed of a transparent conductive material such as a Mg—Ag alloy (extremely thin film) or ITO.

If the light-emitting element layer 5 is an OLED layer, holes and electrons recombine in the EL layer 24 due to the drive current flowing between the anode 22 and the cathode 25, to produce excitons that fall to the ground state to emit light. Since the anode 22 is light-reflective and the cathode 25 is transparent, the display light emitted by the EL layer 24 travels upward, thereby achieving “top emission.”

The light-emitting element layer 5 does not necessarily constitute a part of an OLED and may constitute a part of an inorganic light-emitting diode or a quantum-dot light-emitting diode.

The sealing layer 6 is transparent and includes: an inorganic sealing film 26 covering the cathode 25; an organic sealing film 27 overlying the inorganic sealing film 26; and an inorganic sealing film 28 covering the organic sealing film 27. The sealing layer 6, covering the light-emitting element layer 5, prevents permeation into the light-emitting element layer 5 of foreign objects such as water and oxygen.

Each inorganic sealing film 26 and 28 is a silicon oxide film, a silicon nitride film, or a silicon oxynitride film, formed by, for example, CVD, or a stack of these films. The organic sealing film 27 is transparent and thicker than the inorganic sealing films 26 and 28 and may be made of, for example, an organic material, such as acrylic, that can be applied by coating.

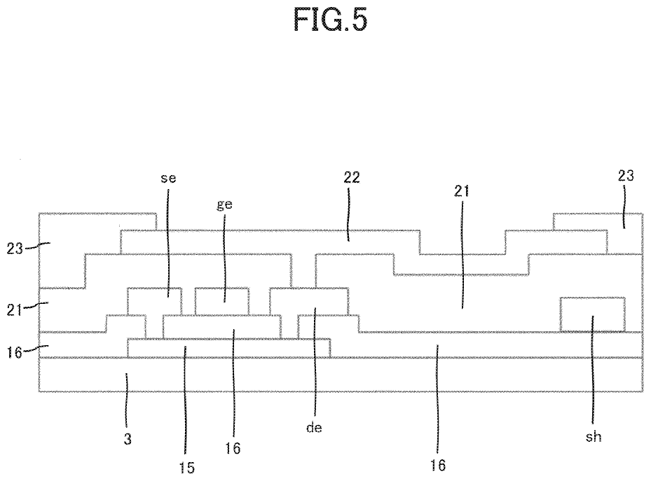

FIG. 4 is a flow chart representing a method of forming a TFT layer and a light-emitting element layer in accordance with Embodiment 1. Referring to FIGS. 2 and 4, subsequent to step S1 in FIG. 1, the semiconductor film 15 and a capacitor line CW are formed (step S2a). In this example, the capacitor line CW, which is a conductor, is formed by, for example, reducing a prescribed region of a patterned oxide semiconductor film. A scan signal line GL is formed in the same layer as the capacitor line CW.

Next, the inorganic insulating film 16, which is a gate insulating film, is formed (step S2b). The gate electrode GE, the gate line GH, the anode 22, the source electrode SE, and the source line SH are then formed in the same step (step S2c). A data signal line (not shown) to which a gray level signal is supplied is formed in the same layer as the source line SH. The gate line GH is connected to the capacitor line CW via a contact hole CHc formed in the inorganic insulating film 16.

Next, the electrode cover film 23 is formed (step S3a). In this example, the electrode cover film 23 is formed by patterning an applied organic insulating film by photolithography so as to cover an edge of the anode 22. An opening in the electrode cover film 23 determines a light-emitting region of the subpixel.

Next, the EL layer 24 is formed by vapor deposition using a fine metal mask (FMM) (step S3b). The cathode 25 is then formed across all the subpixels (step S3c).

In the transistor in the TFT layer 4, the gate electrode GE is disposed so as to overlap the semiconductor film 15 with the inorganic insulating film 16 intervening therebetween; contact holes CHa and CHs overlapping the semiconductor film 15 are formed through the inorganic insulating film 16; the contact hole CHa overlaps a portion 22h of the anode 22; a portion of the source electrode SE residing inside the contact hole CHs is in contact with the semiconductor film 15; the portion 22h of the anode 22 residing inside the contact hole CHa is in contact with the semiconductor film 15; the semiconductor film 15 serves as the channel of the transistor; and the anode 22 serves as the drain electrode of the transistor.

Additionally, the electrode cover film 23 covers the source electrode SE and the gate electrode GE. The capacitor needed in the subpixel circuit is formed, for example, where the capacitor line CW connected to the gate line GH via the contact hole CHc overlaps the source line SH, as shown in FIG. 2(b). Alternatively, the capacitor may be formed where the capacitor line CW connected to the source line SH overlaps the gate line GH.

When compared with the structure example shown in FIG. 5, the structure in accordance with Embodiment 1 obviates the need for the source electrode se, a drain electrode de, and the source line sh disposed below the anode 22, thereby enabling prevention of adverse effects on the light-emitting element layer of the unevenness formed by the source electrode se, the drain electrode de, and the source line sh which generally have a large thickness. This structure also obviates the need for a planarization film 21 that is made typically of a costly material. Cost is greatly lowered owing to the lack of need for the costly planarization film and the lack of need for a step of manufacturing the planarization film.

In addition, as shown in FIG. 3, an ITO film Ax in the anode 22 is in contact with the semiconductor film 15 containing an oxide semiconductor (e.g., In—Ga—Zn—O-based semiconductor). The structure therefore realizes a transistor that has a low contact resistance and excellent switching properties.

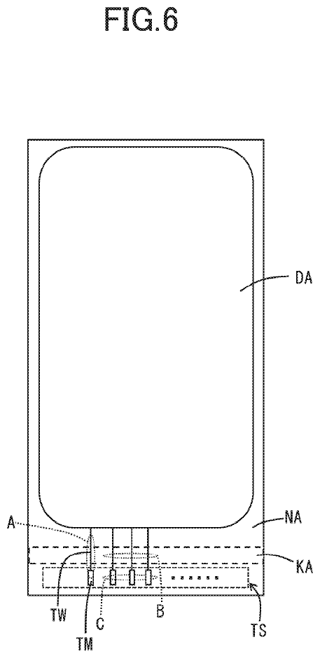

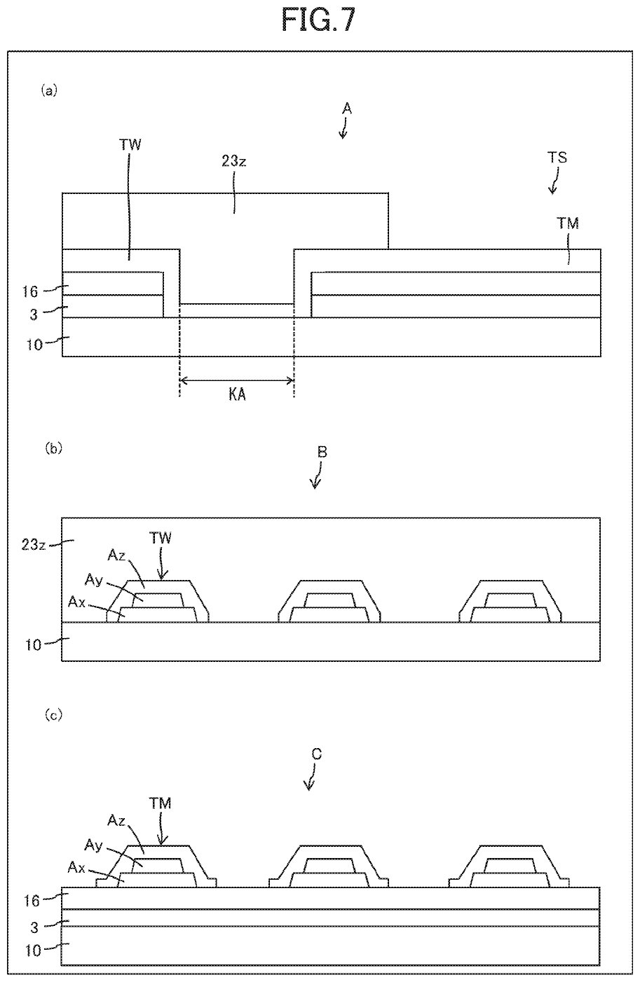

FIG. 6 is a plan view of an exemplary structure of a display device. FIG. 7 is a set of cross-sectional views of parts of FIG. 6. In FIGS. 6 and 7, the substrate 10 is a flexible substrate (e.g., a substrate containing a resin film such as a polyimide film). A terminal section TS and a bendable portion KA, both for inputting signals, are provided in a non-display section NA surrounding a display section DA. The bendable portion KA is located between the display section DA and the terminal section TS for inputting signals. A terminal line TW drawn out of the display section DA is routed through the bendable portion KA and connected to a terminal TM of the terminal section TS.

The terminal line TW and the terminal TM are formed in the same layer (and of the same material) as the anode 22 (see FIG. 2) in the display section DA. In the bendable portion KA, a barrier film 3 and the inorganic insulating film 16 are penetrated. Therefore, the terminal line TW is therefore formed on a resin film (e.g., a polyimide film) in the flexible substrate 10 and covered by an organic insulating film 23z residing in the same layer as the electrode cover film 23.

Referring to FIG. 7(b), the terminal line TW and the terminal TM include the ITO film Ax (first film in the same layer as the ITO film AX shown in FIG. 3), a Ag-containing alloy film Ay (second film in the same layer as the alloy film AY shown in FIG. 3) on the ITO film Ax, and an ITO film Az (third film in the same layer as the ITO film AZ shown in FIG. 3) formed so as to cover the top and end faces of the alloy film Ay. In this structure, the alloy film Ay is covered by the ITO film Az (the alloy film Ay is not exposed), which can restrain degradation of the alloy film Ay.

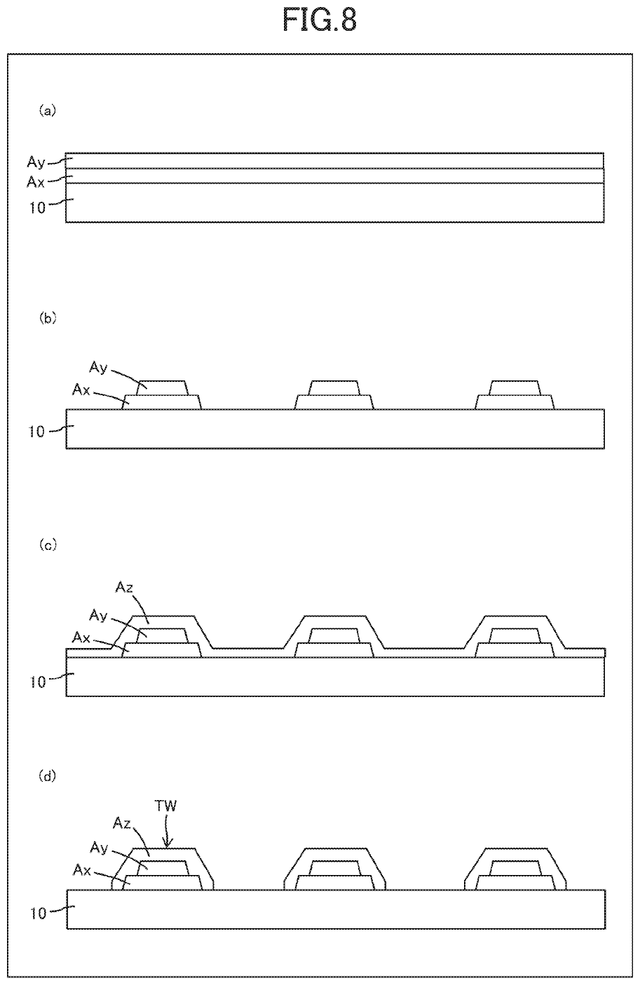

FIG. 8 is a set of cross-sectional views illustrating steps of forming terminal lines in a bendable portion. First, as shown in FIG. 8(a), the ITO film Ax and the alloy film Ay are formed one by one. Next, as shown in FIG. 8(b), the ITO film Ax and the alloy film Ay are collectively patterned. In this patterning, because the alloy film Ay is more easily etched than the ITO film Ax, the overlying alloy film Ay is formed wider than the ITO film Ax which resides below the alloy film Ay. Next, as shown in FIG. 8(c), the ITO film Az is formed so as to cover the ITO film Ax and the alloy film Ay. Next, as shown in FIG. 8(d), the ITO film Az is patterned. In this patterning, the ITO film Az is etched such that the remaining ITO film Az is wider than the remaining ITO film Ax and covers the top and end faces of the alloy film Ay and the end faces of the ITO film Ax.

### Embodiment 2

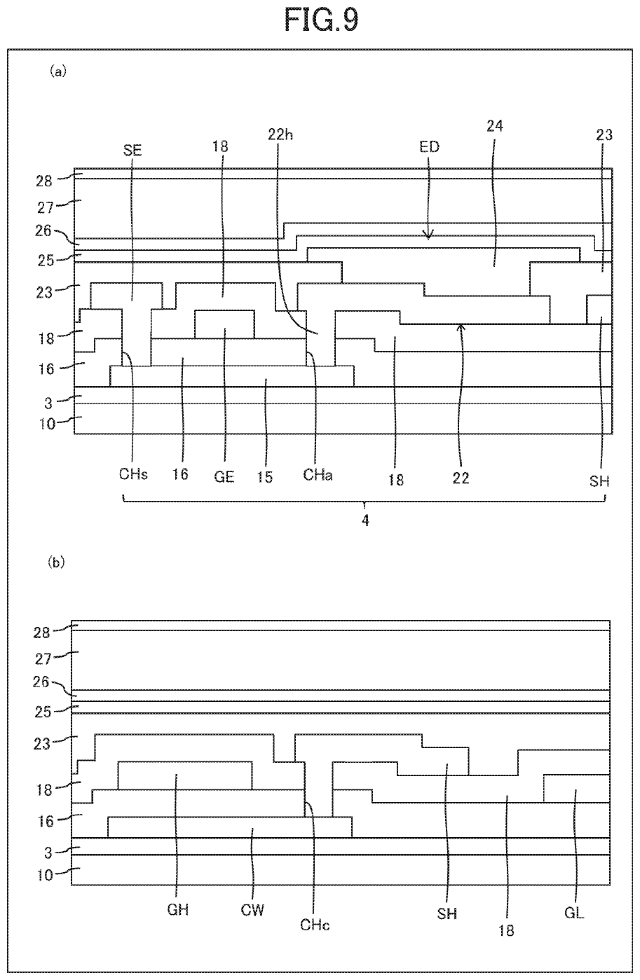

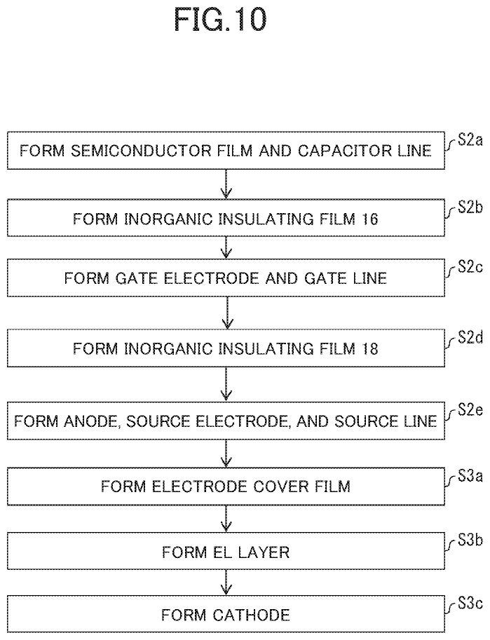

FIG. 9 is a set of cross-sectional views of an exemplary structure of a display device in accordance with Embodiment 2. FIG. 10 is a flow chart representing a method of forming a TFT layer and a light-emitting element layer in accordance with Embodiment 2. In Embodiment 2, an inorganic insulating film 18 is provided overlying the gate electrode GE and underlying the anode 22.

Referring to FIGS. 9 and 10, subsequent to step S1 in FIG. 1, the semiconductor film 15 and the capacitor line CW are formed (step S2a). Next, the inorganic insulating film 16, which is a gate insulating film, is formed (step S2b). Next, the gate electrode GE, the gate line GH, and the scan signal line GL are formed (step S2c). Next, the inorganic insulating film 18, which is a passivation film, is formed so as to cover the gate electrode GE, the gate line GH, and the scan signal line GL (step S2d). The anode 22, the source electrode SE, and the source line SH are then formed in the same step (step S2e). The data signal line (not shown) is formed in the same layer as the source line SH. Next, the electrode cover film 23 is formed (step S3a). Next, the EL layer 24 is formed (step S3b). Next, the cathode 25 is formed (step S3c).

In the transistor in the TFT layer 4, the gate electrode GE is disposed so as to overlap the semiconductor film 15 with the inorganic insulating film 16 intervening therebetween; the contact holes CHa and CHs overlapping the semiconductor film 15 are formed through the inorganic insulating film 16; the contact hole CHa overlaps the portion 22h of the anode 22; a portion of the source electrode SE residing inside the contact hole CHs is in contact with the semiconductor film 15; the portion 22h of the anode 22 residing inside the contact hole CHa is in contact with the semiconductor film 15; the semiconductor film 15 serves as the channel of the transistor; and the anode 22 serves as the drain electrode of the transistor.

Additionally, the electrode cover film 23 covers the source electrode SE and the source line SH. The capacitor needed in the subpixel circuit is formed, for example, where the capacitor line CW connected to the source line SH via the contact hole CHc formed in the inorganic insulating films 16 and 18 overlaps the gate line GH, as shown in FIG. 9(b). Alternatively, the capacitor may be formed where the capacitor line CW connected to the gate line GH overlaps the source line SH.

### Embodiment 3

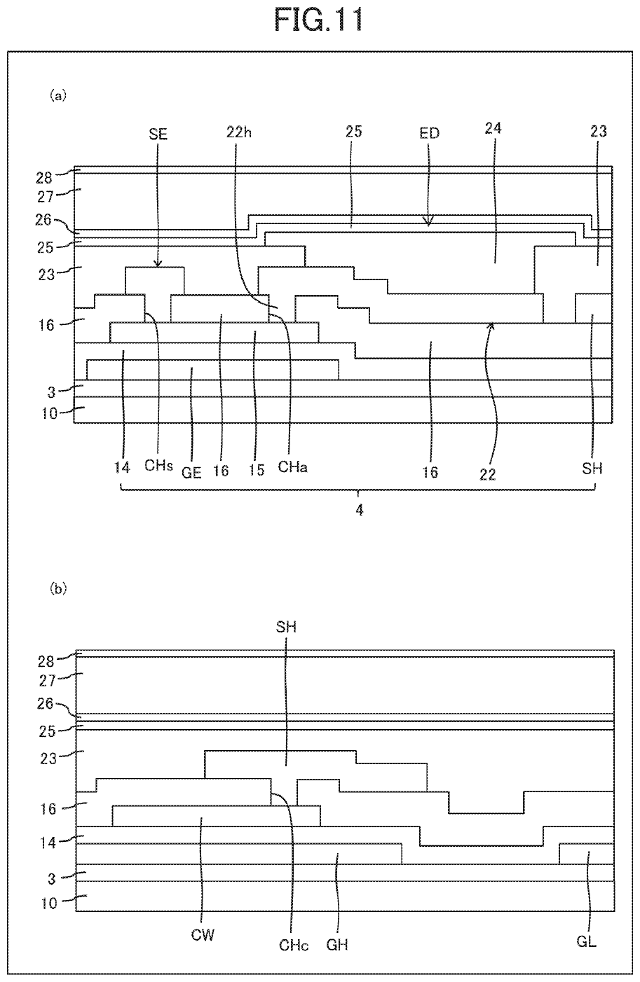

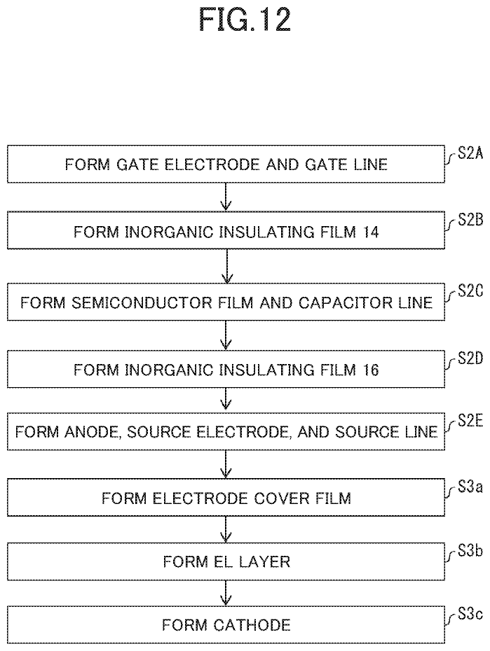

FIG. 11 is a set of cross-sectional views of an exemplary structure of a display device in accordance with Embodiment 3. FIG. 12 is a flow chart representing a method of forming a TFT layer and a light-emitting element layer in accordance with Embodiment 3. In Embodiment 3, the transistor has a bottom gate structure in which the gate electrode GE is disposed below the semiconductor film 15.

As shown in FIGS. 11 and 12, subsequent to step S1 in FIG. 1, the gate electrode GE, the gate line GH, and the scan signal line GL are formed (step S2A). Next, an inorganic insulating film 14, which is a gate insulating film, is formed so as to cover the gate electrode GE, the gate line GH, and the scan signal line GL (step S2B). Next, the semiconductor film 15 and the capacitor line CW are formed (step S2C). Next, the inorganic insulating film 16 is formed (step S2D). Next, the anode 22, the source electrode SE, and the source line SH are formed in the same step (step S2E). The data signal line (not shown) is formed in the same layer as the source line SH. Next, the electrode cover film 23 is formed (step S3a). Next, the EL layer 24 is formed (step S3b). Next, the cathode 25 is formed (step S3c).

In the transistor in the TFT layer 4, the gate electrode GE is disposed so as to overlap the semiconductor film 15 with the inorganic insulating film 14 intervening therebetween; the contact holes CHa and CHs overlapping the semiconductor film 15 are formed through the inorganic insulating film 16; the contact hole CHa overlaps the portion 22h of the anode 22; a portion of the source electrode SE residing inside the contact hole CHs is in contact with the semiconductor film 15; the portion 22h of the anode 22 residing inside the contact hole CHa is in contact with the semiconductor film 15; the semiconductor film 15 serves as the channel of the transistor; and the anode 22 serves as the drain electrode of the transistor.

Additionally, the electrode cover film 23 covers the source electrode SE and the source line SH. The capacitor needed in the subpixel circuit is formed, for example, where the capacitor line CW connected to the source line SH via the contact hole CHc formed in the inorganic insulating film 16 overlaps the gate line GH as shown in FIG. 11(b). Alternatively, the capacitor may be formed where the capacitor line CW connected to the gate line GH overlaps the source line SH.

### General Description

The electro-optical elements, the luminance and transmittance of which are controlled through current, provided in the display device in accordance with the present embodiment are not limited in any particular manner. The display device in accordance with the present embodiment may be, for example, an organic EL (electroluminescence) display device including OLEDs (organic light-emitting diodes) as electro-optical elements, an inorganic EL display device including inorganic light-emitting diodes as electro-optical elements, or a QLED display device including QLEDs (quantum dot light-emitting diodes) as electro-optical elements.

The present invention is not limited to the description of the embodiments above. Embodiments based on a proper combination of technical means disclosed in different embodiments are encompassed in the technical scope of the present invention. Furthermore, new technological features can be created by combining different technological means disclosed in the embodiments.

### Aspect 1

A display device including: a substrate; a semiconductor film; an inorganic insulating film overlying the semiconductor film; and light-emitting elements overlying the inorganic insulating film, each of the light-emitting elements including a first electrode and a second electrode, wherein the inorganic insulating film has a contact hole therethrough, and a portion of the first electrode overlaps the contact hole so that the portion of the first electrode is in contact with the semiconductor film in the contact hole.

### Aspect 2

The display device of, for example, aspect 1, wherein the first electrode is light-reflective.

### Aspect 3

The display device of, for example, aspect 1 or 2, wherein the semiconductor film contains an oxide semiconductor.

### Aspect 4

The display device of, for example, aspect 3, wherein the first electrode is a stack of a lower ITO film, a Ag-containing alloy film, and an upper ITO film that are arranged in this order when viewed from the substrate.

### Aspect 5

The display device of, for example, any one of aspects 1 to 4, further including an electrode cover film covering an edge of the first electrode and overlapping the contact hole.

### Aspect 6

The display device of, for example, any one of aspects 1 to 5, further including: a gate electrode overlapping the semiconductor film with the inorganic insulating film intervening therebetween; and a source electrode in contact with the semiconductor film, wherein the gate electrode and the source electrode are formed in a same layer as the first electrode.

### Aspect 7

The display device of, for example, aspect 6, further including an electrode cover film covering an edge of the first electrode, the gate electrode, and the source electrode.

### Aspect 8

The display device of, for example, any one of aspects 1 to 5, further including: a gate electrode overlapping the semiconductor film with the inorganic insulating film intervening therebetween; and a source electrode in contact with the semiconductor film, wherein the gate electrode is formed underlying the first electrode, and the source electrode is formed in a same layer as the first electrode.

### Aspect 9

The display device of, for example, aspect 6 or 8, wherein the semiconductor film contains an oxide semiconductor, there is provided a capacitor line including a reduced product of the oxide semiconductor in a same layer as the semiconductor film, and the capacitor line forms a capacitor in combination with wiring in a same layer as the gate electrode or with wiring in a same layer as the source electrode.

### Aspect 10

The display device of, for example, aspect 4, further including: a terminal section in a non-display section surrounding a display section, the terminal section being configured to receive an incoming external signal; a bendable portion between the display section and the terminal section; and a terminal line drawn out of the display section, routed through the bendable portion, and connected to the terminal section, wherein in the bendable portion, the inorganic insulating film is penetrated, and the terminal line is formed in a same layer as the first electrode.

### Aspect 11

The display device of, for example, aspect 10, wherein the terminal section includes a terminal in a same layer as the first electrode.

### Aspect 12

The display device of, for example, aspect 10 or 11, further including: an organic insulating film in a same layer as an electrode cover film covering an edge of the first electrode; a barrier film underlying the semiconductor film; and a resin film underlying the barrier film, wherein in the bendable portion, the barrier film is penetrated, and the terminal line, in the bendable portion, has a bottom face in contact with the resin film and has a top face in contact with the organic insulating film.

### Aspect 13

The display device of, for example, aspect 11, wherein the terminal line and the terminal include a first film in a same layer as the lower ITO film, a second film in a same layer as the alloy film, and a third film in a same layer as the upper ITO film, the second film is formed smaller in width than the first film, and the third film is formed so as to cover an end face of the first film and an end face of the second film.

### Aspect 14

The display device of, for example, any one of aspects 1 to 13, wherein each of the light-emitting elements is an OLED, and the first electrode is an anode or cathode of the OLED.

### REFERENCE SIGNS LIST

2 Display Device
3 Barrier Film
4 TFT Layer
5 Light-emitting Element Layer
6 Sealing Layer
10 Substrate
14, 16, 18 Inorganic Insulating Film
15 Semiconductor Film
22 Anode (First Electrode)
23 Electrode Cover Film
24 EL layer
25 Cathode (Second Electrode)
SE Source electrode
GE Gate Electrode
SH Source Line
GH Gate Line
GL Scan Signal Line
CW Capacitor Line
ED Light-emitting Element

1. A display device comprising:
a substrate;
a semiconductor film;
an inorganic insulating film overlying the semiconductor film; and
light-emitting elements overlying the inorganic insulating film, each of the light-emitting elements including a first electrode and a second electrode, wherein
the inorganic insulating film has a contact hole therethrough,
a portion of the first electrode overlaps the contact hole so that the portion of the first electrode is in contact with the semiconductor film in the contact hole, and
the first electrode is light-reflective.

2. (canceled)

3. The display device according to claim 1 wherein the semiconductor film contains an oxide semiconductor.

4. The display device according to claim 1, wherein the first electrode is a stack of a lower ITO film, a Ag-containing alloy film, and an upper ITO film that are arranged in this order when viewed from the substrate.

5. The display device according to claim 1, further comprising an electrode cover film covering an edge of the first electrode and overlapping the contact hole.

6. The display device according to claim 1, further comprising:
a gate electrode overlapping the semiconductor film with the inorganic insulating film intervening therebetween; and
a source electrode in contact with, and electrically connected to, the semiconductor film, wherein
the gate electrode and the source electrode are formed in a same layer as the first electrode.

7. The display device according to claim 6, further comprising an electrode cover film covering an edge of the first electrode, the gate electrode, and the source electrode.

8. The display device according to claim 1, further comprising:
a gate electrode overlapping the semiconductor film with the inorganic insulating film intervening therebetween; and
a source electrode in contact with, and electrically connected to, the semiconductor film, wherein
the gate electrode is formed underlying the first electrode, and
the source electrode is formed in a same layer as the first electrode.

9. The display device according to claim 6, wherein
the semiconductor film contains an oxide semiconductor,
there is provided a capacitor line including a reduced product of the oxide semiconductor in a same layer as the semiconductor film, and
the capacitor line forms a capacitor in combination with wiring in a same layer as the gate electrode or with wiring in a same layer as the source electrode.

10. The display device according to claim 4, further comprising:
a terminal section in a non-display section surrounding a display section, the terminal section being configured to receive an incoming external signal;
a bendable portion between the display section and the terminal section; and
a terminal line drawn out of the display section, routed through the bendable portion, and connected to the terminal section, wherein
in the bendable portion, the inorganic insulating film is penetrated, and the terminal line is formed in a same layer as the first electrode.

11. The display device according to claim 10, wherein the terminal section includes a terminal in a same layer as the first electrode.

12. The display device according to claim 10 further comprising:
an organic insulating film in a same layer as an electrode cover film covering an edge of the first electrode;
a barrier film underlying the semiconductor film; and
a resin film underlying the barrier film, wherein
in the bendable portion, the barrier film is penetrated, and
the terminal line, in the bendable portion, has a bottom face in contact with the resin film and has a top face in contact with the organic insulating film.

13. The display device according to claim 11, wherein
the terminal line and the terminal include a first film in a same layer as the lower ITO film, a second film in a same layer as the alloy film, and a third film in a same layer as the upper ITO film,
the second film is formed smaller in width than the first film, and
the third film is formed so as to cover an end face of the first film and an end face of the second film.

14. The display device according to claim 1, wherein
each of the light-emitting elements is an OLED, and
the first electrode is an anode or cathode of the OLED.
